(19) United States
(12) Patent Application Publication
(10) Pub. No.: US 2002/0132458 A1
(43) Pub. Date: Sep. 19, 2002

(54) Method for fabricating a MOS transistor of an embedded memory

(76) Inventors: Sun-Chieh Chien, Hsin-Chu City (TW); Chien-Li Kuo, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/803,880

(22) Filed: Mar. 13, 2001

(51) Int. Cl. H01L 21/4763; H01L 21/3205; H01L 21/8242; H01L 21/336

(52) U.S. Cl. 438/593; 438/594; 438/258; 438/241

(57) ABSTRACT

A memory array area and a periphery circuit region on the surface of a semiconductor wafer are defined, and a gate oxide layer, an polysilicon layer and a dielectric layer are sequentially formed on the wafer. Next, the polysilicon layer in the memory array area is implanted to form a doped polysilicon layer. The doped polysilicon layer in the memory array area is etched down to a predetermined depth and the dielectric layer in the memory array area is removed. A silicide layer and a protection layer are formed on the surface of the semiconductor wafer. An etching process is used to form a plurality of gates in the memory array area and an in-situ etching of the protection layer and the silicide layer in the periphery circuit region is performed. Finally, the polysilicon layer in the periphery circuit region is etched to form a plurality of gates. A spacer, a source and a drain are formed around each gate.

### BACKGROUND OF THE INVENTION

1. Field of the Invention

The present invention relates to a method of manufacturing a MOS transistor of an embedded memory.

2. Description of the Prior Art

With increasing integration, the present trend of manufacturing semiconductor integrated circuits is to integrate memory cell arrays and high-speed logic circuit elements onto a single chip. An embedded memory composed of memory arrays and logic circuits significantly reduces the circuit area and hastens the signal processing speed.

Please refer to FIG. 1 to FIG. 5. FIG. 1 to FIG. 5 are cross-sectional diagrams of a prior art method for manufacturing a metal-oxide-semiconductor (MOS) transistor of an embedded memory on a semiconductor wafer 10. As shown in FIG. 1, the surface of the silicon substrate 12 is divided into a memory array area 14 and a periphery circuit region 16. The memory array area 14 contains a cell well 18, and the periphery circuit region 14 contains at least one N-well 20 and at least one P-well 22. Each region is separated by several shallow trench isolation structures 23.

The prior art method first involves forming a gate oxide layer 21, a polysilicon layer 24, a polycide layer 26 and cap layer 28 composed of silicon nitride, respectively, on the surface of the semiconductor wafer 10. Then, as shown in FIG. 2, a photoresist layer 30 is formed above the cap layer 28 followed by the use of a lithographic process to simultaneously define gate patterns of both the memory array area 14 and the periphery circuit region 16 in the photoresist layer 30. Thereafter, the patterned photoresist layer 30 is used as a mask layer to perform an etching process for removing the cap layer 28, the polycide layer 26 and the polysilicon layer 24 down to the surface of the gate oxide layer 21 so as to simultaneously form a plurality of gates 32 above the cell well 18 of the memory array area 14 and a plurality of gates 34 above the N-well 20 and P-well 22 of the periphery circuit region 16.

As shown in FIG. 3, the photoresist layer 30 above the cap layer 28 is completely removed, followed by performing an ion implantation process to form a doped region (not shown) on the surface of the silicon substrate 12 adjacent to the gates 32, 34. Thereafter, a rapid thermal process (RTP) is performed to drive dopants in the doped region into the silicon substrate 12 so as to form lightly doped drain (LDD) 36 of each MOS transistor.

As shown in FIG. 4, a silicon nitride layer (not shown) is deposited on the semiconductor wafer 10 followed by performing an anisotropic etching process to etch back portions of the silicon nitride layer to form a spacer 38 around each gate 32, 34 of the memory array area 14 and the periphery circuit region 16, respectively. Then, an ion implantation process is performed to form a source and drain of each MOS transistor in the periphery circuit region 16. A photoresist layer is first formed to cover the memory array area 14 and gates 32, 34 of the N-well 20. Then, N-type dopants are used to implant the surface of the P-well 22 so as to form a doped region 42, followed by removal of the photoresist layer. Next, another photoresist layer is formed to completely cover the memory array area 14 and the gate 34 of the P-well 22. Then, P-type dopants are used to implant the N-well 20 of the periphery circuit region 16 so as to form a doped region 40. Thereafter, a rapid thermal process is used to drive dopants of each doped region 40, 42 into the silicon substrate 12 so as to form the source and the drain of each MOS transistor in the periphery circuit region 16.

Finally, as shown in FIG. 5, a salicide block (SAB) layer 44 is formed on the silicon substrate 12 of the memory array area 14. Then, a self-aligned silicide process is performed in the periphery circuit region 16 for forming a salicide layer 46 on the surface of each source and drain so as to finish the process of manufacturing a MOS transistor of an embedded memory according to the prior art method.

In the periphery circuit region, issues associated with boron penetration in the PMOS gate formed above the N-well can occur. The depth of the polysilicon layer of the gate is generally increased to 2000˜3000 Å for preventing boron dopants from penetrating the gate oxide layer of the PMOS gate into the silicon substrate. Consequently, in the prior art method of manufacturing an embedded memory, the polysilicon layer of the gate structures in the memory array area, which are formed together with that in the periphery circuit region, will have a greater thickness than when manufactured in an ordinary memory process. As the integration of the memory array area increases, the aspect ratio between gates greatly increases. Thus, over-hanging can easily occur between two neighboring gates in the memory array area when filling the ILD layer. A void bridge may then be formed, creating an electrical connection with a contact plug formed between two neighboring gates, and leading to short-circuiting.

### SUMMARY OF THE INVENTION

It is a primary objective of the present invention to provide a method of manufacturing a MOS transistor of an embedded memory. The method reduces the gate depth of the memory array area so as to decrease the aspect ratio between gates and to prevent the formation of void bridges between two gates when filling the ILD layer in the memory array area.

The method of the present invention involves first defining a memory array area and a periphery circuit region on the surface of the semiconductor wafer and to sequentially deposit a gate oxide layer, an polysilicon layer and a dielectric layer. Next, the polysilicon layer in the memory array area is implanted to form a doped polysilicon layer. Thereafter, the doped polysilicon layer in the memory array area is etched to a predetermined depth and the dielectric layer in the memory array area is removed. A silicide layer and a protection layer are formed on the surface of the semiconductor wafer. An etching process is used to form a plurality of gates in the memory array area and an in-situ etching of the protection layer and the silicide layer in the periphery circuit region. Finally, the polysilicon layer in the periphery circuit region is etched to form a plurality of gates. A spacer, a source and a drain are then formed around each gate.

The MOS transistor of an embedded memory manufactured by the present invention has a doped polysilicon layer in the memory array area with half the ordinary thickness. Hence, the gate depth is greatly reduced so as to decrease the aspect ratio between gates, and short-circuiting due to the formation of void bridges is prevented.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 5 are cross-sectional diagrams of manufacturing a MOS transistor of an embedded memory according to the prior art.

FIG. 6 to FIG. 18 are cross-sectional diagrams of manufacturing a MOS transistor of an embedded memory according to the present invention.

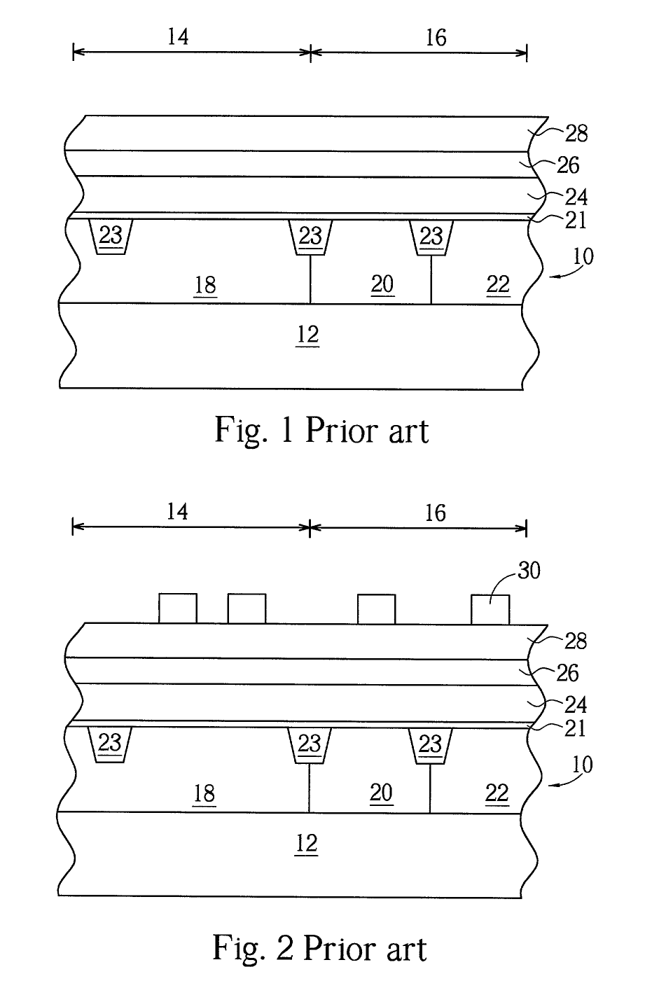

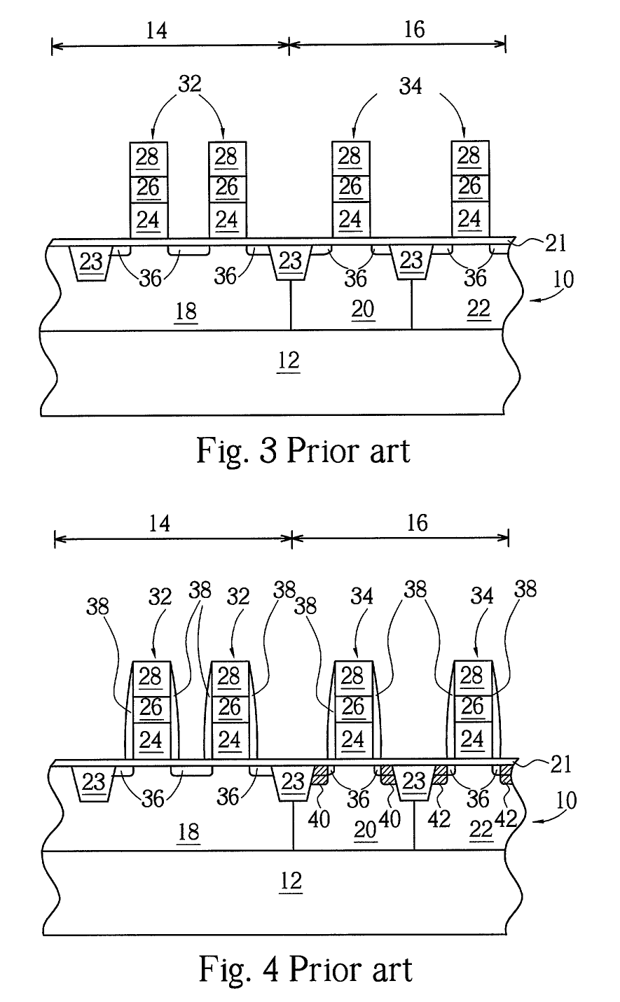

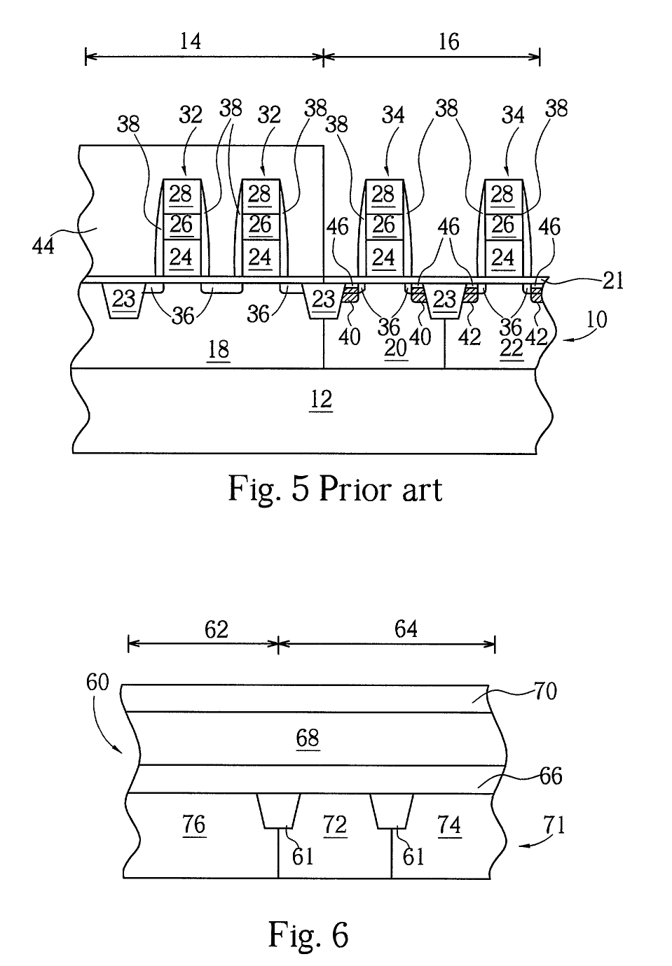

### DETAILED DESCRIPTION OF THE PREFERRED EMBODIMENT

Please refer to FIG. 6 to FIG. 18. FIG. 6 to FIG. 18 are cross-sectional diagrams of manufacturing a MOS transistor of an embedded memory on semiconductor wafer 60 according to the present invention. As shown in FIG. 6, a semiconductor wafer 60 has both a memory array area 62 and a periphery circuit region 64 defined on the surface of a silicon substrate 71. The memory array area 62 comprises at least one cell-well 76, and the periphery circuit region 64 comprises at least one N-well 72 and at least one P-well 74. Several shallow trench isolation (STI) structures 61 are formed to separate each region.

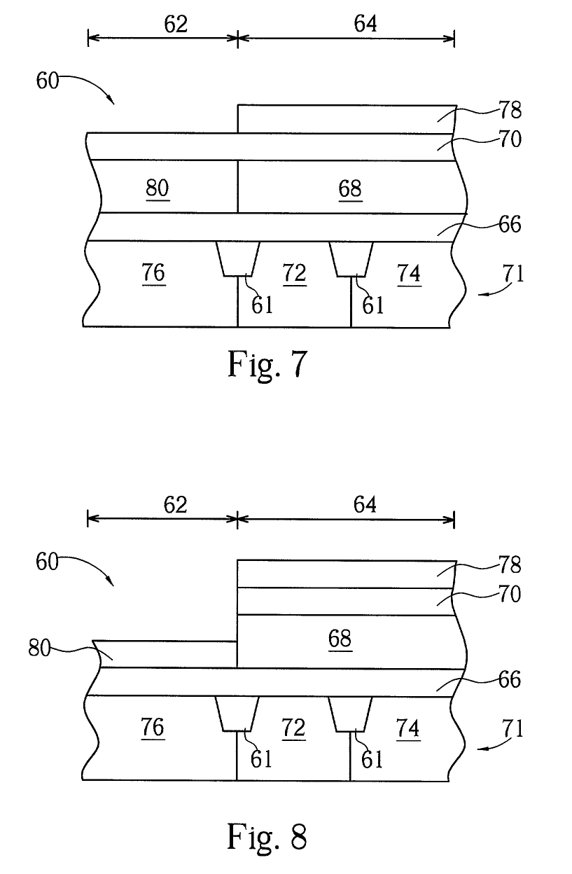

The present invention involves first forming a first dielectric layer 66, a polysilicon layer 68, and a second dielectric layer 70 in order on the surface of the semiconductor wafer 60. Then, as shown in Fig.7, a photoresist layer is formed as a mask layer 78 on the periphery circuit region 64. A first ion implantation process is performed on the polysilicon layer 68 above the memory array area 62 so as to change the polysilicon layer 68 above the memory array area 62 to an N-type doped polysilicon layer 80.

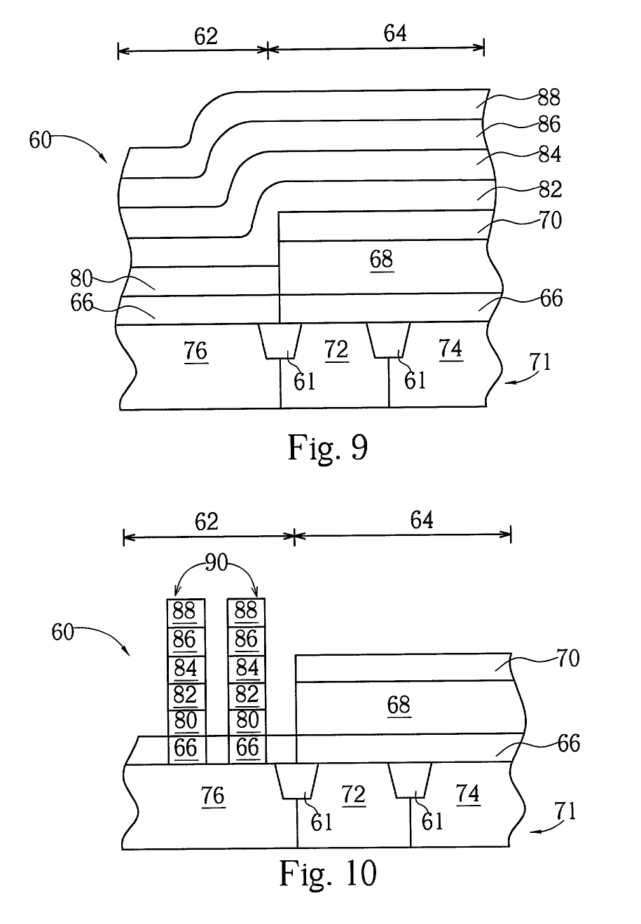

Thereafter, as shown in FIG. 8, an etching process is performed to completely remove the dielectric layer 70 above the memory array area 62, and the doped polysilicon layer 80 is etched down to approximately half of the total depth of the polysilicon layer 68, which is about 1000˜1900 Å. As shown in FIG. 9, after removing the mask layer 78 on the periphery circuit region 64, a silicide layer 82, a silicon-oxy-nitride (SiOₓN_{y}) layer 84, a silicon nitride layer 86, and a photoresist layer 88 are formed in order on the surface of the semiconductor wafer 60. The silicide layer 82 is formed to reduce the contact interface resistance of the doped silicon layer 80, the silicon-oxy-nitride (SiOₓN_{y}) layer 84 is an anti-reflection coating (ARC) layer, and the silicon nitride layer 86 serves as a protection layer.

A photolithographic process is performed so as to define a plurality of gate 90 patterns in the photoresist layer 88 above the cell-well 76 of the memory array area 62. Thereafter, the gate 90 patterns in the photoresist layer 88 are used as a hard mask to etch the silicon nitride layer 56, the silicon-oxy-nitride layer 84, the silicide layer 82, and the doped polysilicon layer 80 that are above the memory array area 62 down to the surface of the dielectric layer 66. Thus, a plurality of MOS transistors gates 90 are formed in the memory array area 62. An in-situ etching of the silicon nitride layer 86, the silicon-oxy-nitride layer 84 and the silicide layer 82 above the periphery circuit region 64 is performed down to the surface of the dielectric layer 70, as shown in FIG. 10.

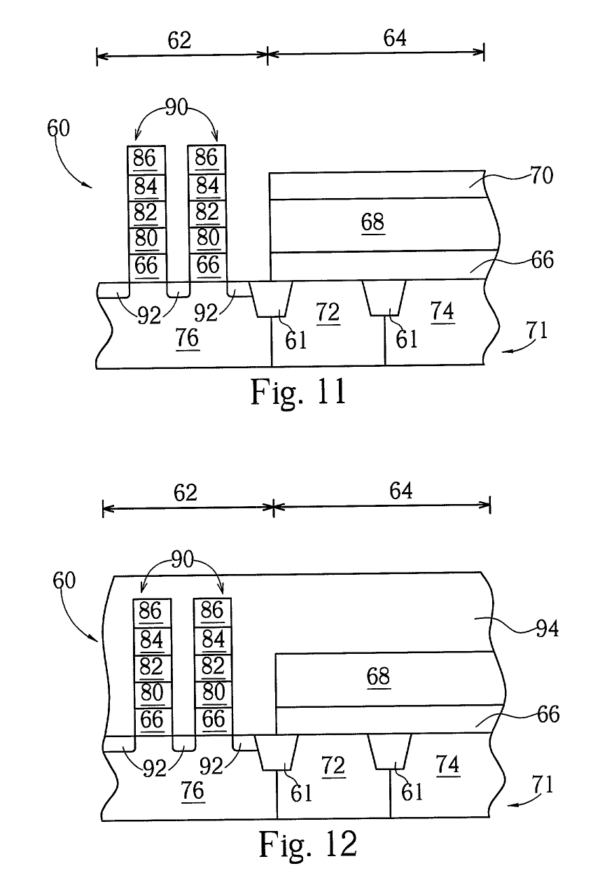

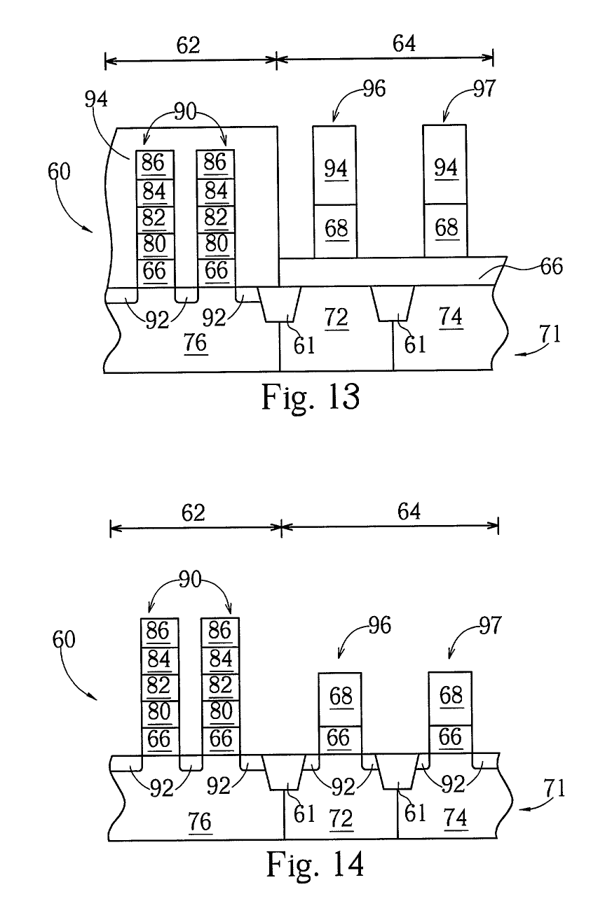

Then, as shown in FIG. 11, an ion implantation process is performed to form a lightly doped drain (LDD) 92 for each MOS transistor in the memory array area 62. As shown in FIG. 12, after removing the photoresist layer 88, the dielectric layer 70 above the periphery circuit region 64 is removed. A photoresist layer 94 and a silicon-oxy-nitride layer (not shown), which is used as an anti-reflection coating (ARC) layer, are formed on the surface of the semiconductor wafer 60. As shown in FIG. 13, a photolithographic process is then performed to define a plurality of gate patterns in the photoresist layer 94 above the P-well 74 and the N-well 72 of the periphery circuit region 64. Next, the gate patterns of the photoresist layer 94 are used as a hard mask to etch the polysilicon layer 98 above the periphery circuit region 64 down to the surface of the dielectric layer 66 so as to form gates 96, 97 for each MOS transistor in the periphery circuit region 64.

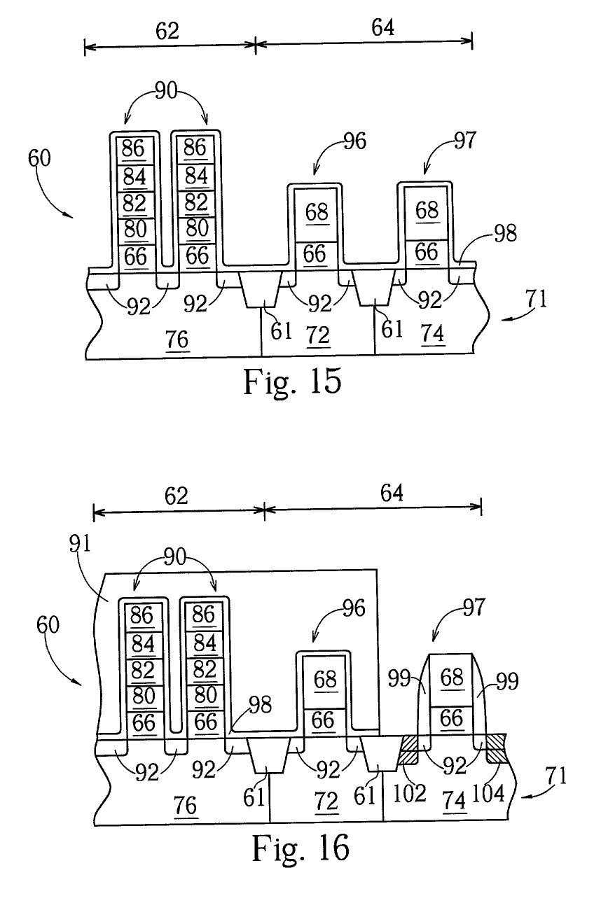

As shown in FIG. 14, an ion implantation process is performed to form a lightly doped drain (LDD) 92 for each MOS transistor in the periphery circuit region 64. After removing the photoresist layer 94, a silicon nitride layer 98 is formed on the surface of the semiconductor wafer 60 to cover the surface of each gate 90, 96 and 97, as shown in FIG. 15.

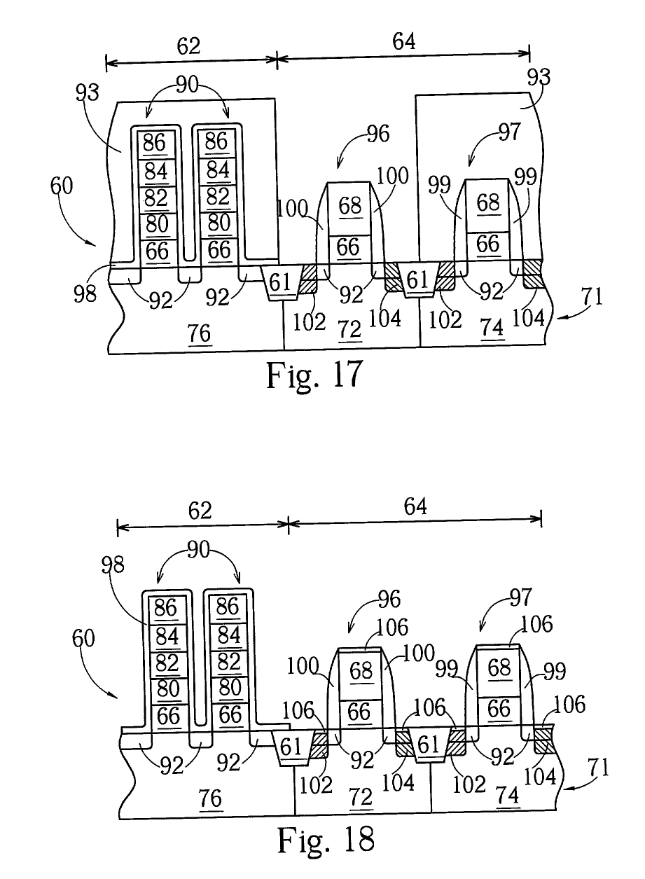

As shown in FIG. 16, a photoresist layer 90 and a photolithographic process are used to define the NMOS position in the periphery circuit region 64. An etching process is then performed to remove portions of the silicon nitride layer 98 around the gate 97 on the P-well 74 of the periphery circuit region 64 so as to form a spacer 99. Next, an ion implantation process is performed to form a source 102 and a drain 104 of the NMOS transistor on the P-well 74, and the photoresist layer 91 is removed. Thereafter, as shown in FIG. 17, a photoresist layer 93 and a photolithographic process are also used to define the PMOS position in the periphery circuit region 64. An etching process is then performed to remove portions of the silicon nitride layer 98 around the gate 96 on the N-well 72 of the periphery circuit region 64 so as to form a spacer 100. Next, an ion implantation process is performed to form a source 102 and a drain 104 of the PMOS transistor on the N-well 72. Finally, the photoresist layer 93 is removed.

After the formation of the source 102 and the drain 104 of each MOS transistor in the periphery circuit region 64, a metal layer (not shown), made of Co, is formed on the surface of the semiconductor wafer 60. The metal layer covers the surfaces of the sources 102, the drains 104, and the gates 96, 97 in the periphery circuit region 64. Then, a first rapid thermal process (RTP) is performed at a temperature that is between 400° C. and 600° C. for a duration of 10 to 50 seconds. A salicide layer 106 is formed on the surfaces of each source 102, drain 104 and gate 96, 97 in the periphery circuit region 64. A wet etching process is performed to remove the portions of the metal layer that do not react with the surface of the semiconductor wafer 60. Finally, a second rapid thermal process (RTP) is performed at a temperature that is between 600° C. and 800° C. for a duration of 10 to 50 seconds. The Co₂Si and CoSi of the salicide layer 106 thus react to form CoSi₂, which has a lower resistance, as shown in FIG. 18. Ti, Ni, or Mo can replace the Co that is used to form the metal layer.

The method of the present invention for manufacturing a MOS transistor of an embedded memory involves first etching the doped polysilicon layer of the memory array area down to about half of the ordinary thickness. The thickness of gates in the memory array area is thus significantly reduced in consideration of preventing boron penetration of the periphery circuit region, and so the aspect ratio between gates is consequently reduced. Thus, short-circuiting as a result of the formation of void bridges is prevented.

In contrast to the prior art method for manufacturing a MOS transistor of an embedded memory, the height of gates in the memory array area manufactured by the present invention is decreased by about 1000˜1900 Å. Hence, the thickness of the gate in the memory array area is noticeably reduced. When filling the ILD layer, the formation of void bridges between two neighboring gates because of the high aspect ratio of the gates in the memory array area is consequently avoided.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for fabricating a metal oxide semiconductor (MOS) transistor of an embedded memory, the method comprising:
providing a semiconductor wafer with both a memory array area and a periphery circuit region defined on the surface of the semiconductor wafer;
forming a first dielectric layer, a polysilicon layer, and a second dielectric layer in order on the surface of the semiconductor wafer;
performing a first ion implantation process on the polysilicon layer above the memory array area so as to change the polysilicon layer above the memory array area to a doped polysilicon layer;
performing an etching process to completely remove the second dielectric layer above the memory array area and etching the doped polysilicon layer to a predetermined depth;
forming a silicide layer, a protection layer, and a first photoresist layer in order on the surface of the semiconductor wafer;
performing a first photolithographic process so as to define a plurality of gate patterns in the first photoresist layer above the memory array area;
using the gate patterns in the first photoresist layer as a hard mask to etch the protection layer, the silicide layer, and the doped polysilicon layer that are above the memory array area down to the surface of the first dielectric layer, and an in-situ etching of the protection layer and the silicide layer that are above the second dielectric layer down to the surface of the second dielectric layer;
performing a second ion implantation process to form a lightly doped drain (LDD) of each MOS transistor in the memory array area;
removing the first photoresist layer and the second dielectric layer above the periphery circuit region;
forming a second photoresist layer on the surface of the semiconductor wafer;
performing a second photolithographic process to define a plurality of gate patterns in the second photoresist layer above the periphery circuit region;
using the gate patterns of the second photoresist layer as a hard mask to etch the polysilicon layer above the periphery circuit region down to the surface of the first dielectric layer so as to form gates of each MOS transistor in the periphery circuit region;
performing a third ion implantation to form a lightly doped drain (LDD) of each MOS transistor in the periphery circuit region;
removing the second photoresist layer;
forming a silicon nitride layer on the surface of the semiconductor wafer to cover the surface of each gate;
performing an etching process to remove portions of the silicon nitride layer in the periphery circuit region so as to form a spacer for each gate in the periphery circuit region; and
performing a forth ion implantation process to form a source and a drain of each MOS transistor in the periphery circuit region.

2. The method of claim 1 wherein the first dielectric layer is composed of silicon dioxide (SiO₂) and serves as the gate oxide layer for each MOS transistor.

3. The method of claim 1 wherein the predetermined depth is approximately half of the total depth of the polysilicon layer.

4. The method of claim 1 wherein the protection layer is composed of silicon nitride, and a silicon-oxy-nitride (SiOₓN_{y}) layer serving as an anti-reflection coating (ARC) layer is disposed between the protection layer and the silicide layer.

5. The method of claim l wherein a silicon-oxy-nitride (SiOₓN_{y}) layer serving as an anti-reflection coating (ARC) layer is formed on the surface of the semiconductor wafer before the second photoresist layer is formed on the surface of the semiconductor wafer.

6. The method of claim 5 wherein after the second photoresist layer is removed, the silicon-oxy-nitride (SiOₓN_{y}) layer below the second photoresist layer is also removed.

7. The method of claim 1 wherein after the formation of the source and the drain of each MOS transistor in the periphery circuit region, the method also comprises:
forming a metal layer on the surface of the semiconductor wafer, the metal layer covering the surfaces of the sources, the drains, and the gates in the periphery circuit region;
performing a first rapid thermal process (RTP);
performing a wet etching process to remove the portions of the metal layer that do not react with the surface of the semiconductor wafer; and
performing a second rapid thermal process (RTP).

8. The method of claim 7 wherein the metal layer is composed of cobalt (Co), titanium(Ti), nickel (Ni), or molybdenum (Mo).

9. The method of claim 7 wherein the first rapid thermal process is performed at a temperature that is between 400° C. and 600° C. for a duration of 10 to 50 seconds, and the second rapid thermal process is performed at a temperature that is between 600° C. and 800° C. for a duration of 10 to 50 seconds.

10. A method for fabricating a metal oxide semiconductor (MOS) transistor of an embedded memory, the method comprising:
providing a semiconductor wafer with both a memory array area and a periphery circuit region defined on the surface of the semiconductor wafer, the memory array area comprising at least one cell-well, the periphery circuit region comprising at least one N-well and at least one P-well;
forming a first dielectric layer, a polysilicon layer, and a second dielectric layer in order on the surface of the semiconductor wafer;
performing a first ion implantation process on the polysilicon layer above the memory array area so as to change the polysilicon layer above the memory array area to a doped polysilicon layer;
performing an etching process to completely remove the second dielectric layer above the memory array area and etching the doped polysilicon layer to a predetermined depth;
forming a silicide layer, a protection layer, and a first photoresist layer in order on the surface of the semiconductor wafer;
performing a first photolithographic process so as to define a plurality of gate patterns in the first photoresist layer above the cell-well of the memory array area;
using the gate patterns in the first photoresist layer as a hard mask to etch the protection layer, the silicide layer, and the doped polysilicon layer above the memory array area down to the surface of the first dielectric layer, and an in-situ etching of the protection layer and the silicide layer above the periphery circuit region down to the surface of the second dielectric layer;
removing the first photoresist layer;
performing a second ion implantation process to form lightly doped drains (LDD) for each MOS transistor in the memory array area;
removing the second dielectric layer above the periphery circuit region;
forming a second photoresist layer on the surface of the semiconductor wafer;
performing a second photolithographic process to define a plurality of gate patterns in the second photoresist layer above the N-well and the P-well of the periphery circuit region;
using the gate patterns of the second photoresist layer as a hard mask to etch the polysilicon layer above the periphery circuit region down to the surface of the first dielectric layer so as to form gates for each MOS transistor in the periphery circuit region;
removing the second photoresist layer;
performing a third ion implantation to form lightly doped drains (LDD) for each MOS transistors in the periphery circuit region;
forming a silicon nitride layer on the surface of the semiconductor wafer to cover the surfaces of the gates;
etching the silicon nitride layer adjacent to each gate above the P-well of the periphery circuit region to form a spacer, and performing a third ion implantation process to form a source and a drain of an NMOS transistor on the P-well; and
etching the silicon nitride layer adjacent to each gate above the N-well of the periphery circuit region to form a spacer, and performing a forth ion implantation process to form a source and a drain of a PMOS transistor on the N-well.

11. The method of claim 10 wherein the first dielectric layer is composed of silicon dioxide (SiO₂) and serves as the gate oxide layer for each MOS transistor.

12. The method of claim 10 wherein the predetermined depth is approximately half of the total depth of the polysilicon layer.

13. The method of claim 10 wherein the protection layer is composed of silicon nitride, and a silicon-oxy nitride (SiOₓN_{y}) layer serving as an anti-reflection coating (ARC) layer is disposed between the protection layer and the silicide layer.

14. The method of claim 10 wherein a silicon-oxy-nitride (SiOₓN_{y}) layer serving as an anti-reflection coating (ARC) layer is formed on the surface of the semiconductor wafer before the second photoresist layer is formed on the surface of the semiconductor wafer.

15. The method of claim 14 wherein after the second photoresist layer is removed, the silicon-oxy-nitride (SiOₓN_{y}) layer below the second photoresist layer is also removed.

16. The method of claim 10 wherein after the formation of the source and the drain of each MOS transistor in the periphery circuit region, the method also comprises:
forming a metal layer on the surface of the semiconductor wafer, the metal layer covering the surfaces of the sources, the drains, and the gates in the periphery circuit region;
performing a first rapid thermal process (RTP);
performing a wet etching process to remove the portions of the metal layer that do not react with the surface of the semiconductor wafer; and
performing a second rapid thermal process (RTP).

17. The method of claim 16 wherein the metal layer is composed of cobalt (Co), titanium (Ti), nickel (Ni) or molybdenum (Mo).

18. The method of claim 16 wherein the first rapid thermal process is performed at a temperature that is between 400° C. and 600° C. for a duration of 10 to 50 seconds, and the second rapid thermal process is performed at a temperature that is between 600° C. and 800° C. for a duration of 10 to 50 seconds.
